(19) United States
(12) Patent Application Publication
(10) Pub. No.: US 2002/0092673 A1
(43) Pub. Date: Jul. 18, 2002

(54) Tungsten encapsulated copper interconnections using electroplating

(75) Inventors: Panayotis C. Andricacos, Croton-on-Hudson, NY (US); Steven H. Boettcher, Fishkill, NY (US); Fenton Read McFeely, Ossining, NY (US); Milan Paunovic, Port Washington, NY (US)

Correspondence Address: Connolly Bove Lodge & Hutz LLP, Suite 800, 1990 M Street, N.W., Washington, DC, 20036-3425, US

(73) Assignee: International Business Machines Corporation, Armonk, NY (US)

(21) Appl. No.: 09/760,884

(22) Filed: Jan. 17, 2001

(51) Int. Cl. H05K 1/03

(52) U.S. Cl. 174/256

(57) ABSTRACT

An interconnection structure is provided wherein comprises a substrate having a dielectric layer with a via opening therein; wherein the opening has a barrier layer; and electrodeposited copper.

### FIELD OF THE INVENTION

The present invention relates to interconnection wiring on electronic devices such as on integrated circuit (IC) chips and more particularly to encapsulated copper interconnection in integrated circuits.

### BACKGROUND OF THE INVENTION

In the past, Al—Cu and its related alloys were the preferred alloys for forming interconnections on electronic devices such as integrated circuit chips. The amount of Cu in Al—Cu is typically in the range of 0.3 to 4 percent.

Replacement of Al—Cu by Cu and Cu alloys as a chip interconnection material results in advantages of performance. Performance is improved because the resistivity of Cu and certain copper alloys is less than the resistivity of Al—Cu; thus narrower lines can be used and higher wiring densities will be realized.

The advantages of Cu metallization have been recognized by the semiconductor industry. In fact, the semiconductor industry is rapidly moving away from aluminum and is adopting copper as the material of choice for chip interconnects because of its high conductivity and improved reliability.

Manufacturing of chip interconnects involves many process steps that are interrelated. In particular, copper interconnects are manufactured using a process called “Dual Damascene” in which a via and a line are fabricated together in a single step. A few of the important integration issues that need to be overcome to successfully fabricate Dual Damascene copper interconnects is the continuity of the barrier and seed layer films and the ability of the copper electroplating process to yield seamless and void-free deposits along the Dual Damascene sidewalls, bottom wall and along the center of the wiring. In addition, the International Technology Roadmap for Semiconductors, 1999 Edition, calls for small via diameters and higher aspect ratios in fLiture interconnect metallizations.

In many prior art techniques, copper is electrodeposited on a copper seed layer which in turn is deposited onto a diffusion barrier layer. Both diffusion barrier and Cu seed layer are typically deposited using physical vapor deposition (PVD), ionized physical vapor deposition (IPVD), or chemical vapor deposition (CVD) techniques (Hu et al., Mat.Chem. Phys., 52 1998)5). All of these methods, PVD, IPVD, and CVD require special tooling along with a vacuum.

Accordingly, room exists for improvement in the prior art for simplifying the processing and/or the required layers.

### SUMMARY OF THE INVENTION

The present invention makes it possible to fabricate completely encapsulated copper interconnections for integrated circuits. The present invention makes it possible to directly deposit copper on the barrier layer without requiring a copper seed layer located between the barrier layer and copper.

In particular, the present invention relates to an electronic structure comprising a substrate having a dielectric layer having a via opening therein; the via opening having a sidewalls and bottom surfaces; a barrier layer deposited on the sidewalls and bottom surfaces of the via opening; copper electrodeposited from a bath having a pH of 12.89 or greater on the barrier layer on the sidewall and bottom surfaces of the via opening.

Another aspect of the present invention relates to a method for fabricating an electronic structure which comprises forming an insulating material on a substrate; lithographically defining and forming recesses for lines and/or via in the insulating material in which interconnection conductor material will be deposited; depositing a barrier layer, and electrodepositing copper from a bath having a pH of at least about 12.89 on the barrier layer.

The present invention also relates to structures obtained by the above process.

Another aspect of the present invention relates to plating baths comprising a source of cupric ions and a complexing agent, having a pH of at least 12.89 and a deposition rate of at least 15 mA/cm².

Still other objects and advantages of the present invention will become readily apparent by those skilled in the art from the following detailed description, wherein it is shown and described preferred embodiments of the invention, simply by way of illustration of the best mode contemplated of carrying out the invention. As will be realized the invention is capable of other and different embodiments, and its several details are capable of modifications in various obvious respects, without departing from the invention. Accordingly, the description is to be regarded as illustrative in nature and not as restrictive.

### BRIEF DESCRIPTION OF THE FIGURES

FIG. 1 shows a cross sectional view of a semiconductor insulator, and diffusion barrier substrate for electrodeposition of Cu, according to the present invention.

FIG. 2 is a cross-sectional view of an encapsulated copper interconnection (via hole, line) according to this invention.

### BEST AND VARIOUS MODES FOR CARRYING OUT INVENTION

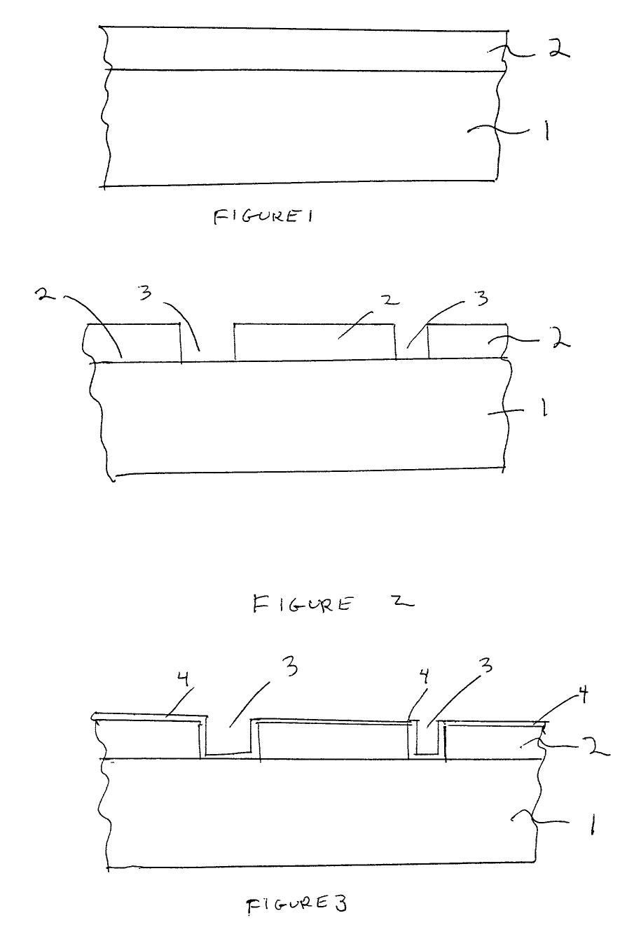

Reference will be made to the figures to facilitate an understanding of the present invention. As shown in FIG. 1, the structures according to the present invention can be obtained by providing an insulating material 2 of a low dielectric constant material such as silicon dioxide on a substrate 1 (e.g. a semiconductor wafer substrate), such as silicon.

Lines and/or vias openings 3 are lithographically defined and formed in the insulating material 2 by well-known techniques as illustrated in FIG. 2. barrier layer 4 is blanket deposited onto the structure as illustrated in FIG. 3.

The barrier layer 4 is typically about 5 to about 200 nanometers thick and more typically about 10 to about 100 nanometers thick.

Typical barrier layers are tungsten, titanium, tantalum, nitrides thereof and alloys thereof. Also, the barrier layer can include two or more layers (e.g. —W/WN bilayer). The preferred barrier layer comprises tungsten.

The barrier layer 4 is typically deposited by chemical vapor deposition (CVD) or by sputtering such as physical vapor deposition (PVD) or ionized physical vapor deposition (IPVD).

The diffusion barriers prevent diffusion of Cu from the interconnection into the insulator (e.g. SiO₂ or other insulator with low dielectric constant, c) and the semiconductor substrate.

A copper or copper alloy layer 5 can be deposited directly onto the diffusion barrier layer 4. The copper can be deposited directly on the barrier layer 4 without any additional seed layer by electrodeposition from a plating both having a pH of about 12.89 or more. The copper plating is employed to fill the lines and/or vias openings 3.

The electroplating copper compositions are aqueous compositions comprising a source of cupric ions, and a complexing agent. The compositions can also include stabilizers, surfactants, levelers and brighteners.

A typical source of cupric ions is CuSO₄. Typical complexing agents are ethylenediamine tetraacetic acid (EDTA) and salts thereof.

Typical stabilizers are sodium cyanide and 2,2′-dipyridil. A typical surfactant is Triton X-114 (polyoxyethylene isooctyl phenyl ether).

The composition has a pH of at least about 12.89 (and preferably about 12.90 to about 13.50) which can be adjusted by adding a pH adjuster such as NaOH or KOH. The depositions typically carried out at about 20° C. to about 35° C. at a deposition rate of about 5 to about 20 mA/cm².

The electroplating is carried out employing a current density of about 5 to about 25 μA/cm² and preferably about 10 to about 20 μA/cm. The electroplating composition typically contains about 0.02 to about 0.211 (molar) of a copper salt such as CuS0₄ and about 0.02 to about 0.511 of a complexing agent such as Na₂EDTA (sodium salt of ethylene diamine tetraacetic acid.

Any layers 3, 4 and 5 present on the top surface of the substrate can be removed by, for example, chemical mechanical polishing to provide a planarized structure with copper being flush with the substrate and to achieve electrical isolation of individual lines and/or vias.

If desired, the chemical mechanical polishing can be carried out prior to depositing the copper in the event of electroless deposition.

The technique of the present invention can be used for single and dual damascene structures.

The following non-limiting examples are presented to further illustrate the present invention.

### EXAMPLE 1

CVD tungsten, about 150 Å thick is deposited onto a patterned SiO₂/Si substrate. Copper is then electrodeposited at room temperature (22° C.), from a bath having a pH of 13.14, and at a constant current of about 20 mA/cm². Apparent substrate surface is about 8.88 cm² and the current is about 177 mA. The electrodeposition composition is LeaRonal Coppermerse 80 solution but without component 80F (the reducing agent). The thickness of copper on the walls of trenches, about 0.43 μm wide and 0.64 μm high, is about 0.28 μm after 1 minute of deposition.

### EXAMPLE 2

The substrate is the same as in Example 1. Copper is electrodeposited at room temperature (22° C.), from a bath having a pH of 13.09, and constant current. For an apparent substrate surface area of about 12.25 cm², the deposition current is about 183.7 mA and the current density about 15 mA/cm². The solution for the electrodeposition of copper has the following composition:

CuSO₄5H₂O) . . . 12.5 g/L

Na2EDTA . . . 37.2 g/L

2,2′ dipyridyl . . . 0156 g/L

Triton X-114 . . . 0.010 mL/L

NaOH to pH . . . 13.09

Mild Agitation

The thickness of copper on walls of trenches (0.43 μm high) was about 0.10 μm after 90 seconds deposition time.

### EXAMPLE 3

Example 2 is repeated except for the current density and the time of copper deposition. For the apparent substrate surface area of about 12.48 cm², the deposition current is about 249.6 mA and the current density about 20 mA/cm². The thickness of copper on walls of trenches (the same dimensions as above) is about 0.42 μm. Thus, trenches are almost filled with the electrodeposited copper.

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. An electronic structure comprising
a substrate having a dielectric layer having a via opening therein; having sidewalls and bottom surfaces;
a barrier layer deposited on the sidewalls and bottom surfaces of the via opening; and copper electrodeposited from a bath having a pH of about 12.89 or greater on the barrier layer on the sidewalls and bottom surfaces of the via opening.

2. The structure of claim 1 wherein the thickness of the copper is about 10 nanometers to about 100 nanometers.

3. The structure of claim 1 wherein the thickness of the copper is about 20 to about 50 nanometers.

4. The structure of claim 1 wherein the barrier layer is selected from the group consisting of tungsten, titanium, tantalum, nitrides thereof, silicon nitrides thereof and alloys thereof.

5. The structure of claim 1 wherein the barrier layer having thickness of at least about 4 nanometers.

6. The structure of claim 1 wherein the dielectric layer comprises silicon dioxide.

7. The structure of claim 1 wherein the via opening has an aspect ratio of greater than 3:1.

8. The structure of claim 1 wherein the barrier layer comprises tungsten.

9. The structure of claim 1 wherein a free of a seed layer between the barrier layer and copper.

10. A method of fabricating an electronic structure which comprises forming an insulating material on a substrate; lithographically defining and forming recesses for lines and/or via having sidewalls and bottom surface in the insulating material in which interconnection conductor material will be deposited;
depositing a barrier layer on sidewalls and bottom surfaces of the recesses;
depositing copper on the barrier layer by electroplating from a both having a pH of about 12.89 or greater, a source of cupric ions and a complexing agent and at a current density of about 5 to about 25 μA/cm².

11. The method of claim 10 wherein the copper is deposited to provide a thickness of about 10 nanometers to about 100 nanometers.

12. The method of claim 10 wherein the copper is deposited to provide a thickness of about 20 to about 50 nanometers.

13. The method of claim 10 wherein the barrier layer is selected from the group consisting of tungsten, alloys of tungsten, titanium, alloys of titanium, titanium nitride, tantalum, tantalum nitride and tantalum silicon nitride.

14. The method of claim 10 wherein the barrier layer has a thickness of at least about 4 nanometers.

15. The method of claim 10 wherein the barrier layer is tungsten.

16. The method of claim 10 wherein the dielectric is silicon dioxide.

17. The method of claim 10 wherein the recess has an aspect ratio of greater than 3:1.

18. The method of claim 10 wherein the electroplating bath is at a room temperature of about 22° C.

19. The method of claim 10 wherein the source of cupric ions is CUSO₄, and the complexing agent is EDTA or salt of thereof.

20. The method of claim 19 wherein the electroplating bath comprises sodium hydroxide or potassium hydroxide.

21. The method of claim 10 wherein the electroplating bath further comprises a stabilizer and surfactant.

22. The method of claim 21 wherein the stabilizer is 2,2′-bipyridyl.

23. The method of claim 10 wherein the plating bath further comprises cyanide ions.

24. An aqueous copper plating bath comprising a source of cupric ions and a complexing agent, having pH at least 12.89 and a deposition rate of at least 15 μA/cm².

25. The plating bath of claim 24, wherein the source of cupric ions is CuSO₄ and the complexing agent is EDTA or salt of thereof.

26. The plating bath of claim 24 which further comprises sodium hydroxide.

27. The method of claim 25 wherein the electroplating bath further comprises a stabilizer and surfactant.

28. The structure obtained by the method of claim 10.
